(19) United States
(12) Patent Application Publication
(10) Pub. No.: US 2006/0205163 A1
(43) Pub. Date: Sep. 14, 2006

(54) METHOD OF FABRICATING A NON-VOLATILE MEMORY

(76) Inventors: Saysamone Pittikoun, Hsinchu County (TW); Chien-Lung Chu, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,145

(22) Filed: Aug. 30, 2005

(30) Foreign Application Priority Data
Mar. 8, 2005 (TW) 94106901

(51) Int. Cl. H01L 21/336

(52) U.S. Cl. 438/287; 438/301

(57) ABSTRACT

A method of fabricating a non-volatile memory is provided. A tunneling dielectric layer, a charge trapping layer and a barrier dielectric layer are sequentially formed over a substrate. Then, a pad conductive layer with openings is formed over the barrier dielectric. Thereafter, the barrier dielectric layer, the charge trapping layer, the tunneling dielectric layer and a portion of the substrate, which are not covered by the pad conductive layer, are removed so as to form trenches. Trench isolation structures are formed in the trenches. Then, a conductive layer is formed over the pad conductive layer. The conductive layer and the pad conductive layer are defined to form stacked gate structures. The barrier dielectric layer, the charge trapping layer and the tunneling dielectric layer, which are not covered by the stacked gate structures, are removed. Doped regions are formed within the substrate adjacent to two sides of each stacked gate structure.

### CROSS-REFERENCE TO RELATED APPLICATION

This application claims the priority benefit of Taiwan application serial no. 94106901, filed on Mar. 8, 2005. All disclosure of the Taiwan application is incorporated herein by reference.

### BACKGROUND OF THE INVENTION

1. Field of the Invention

The present invention relates to a semiconductor memory device, and more particularly to a method of fabricating a non-volatile memory.

2. Description of the Related Art

Memories are semiconductor devices used to store information or data. When a computer processor is powerful, the software executes more programs and operations. Accordingly, a memory with a high capacity is required. In order to fabricate a memory with a high capacity and low cost, the semiconductor devices with high integration level of memory has become the challenge in the semiconductor technology.

Among memory products, the non-volatile memory, which can save, read or erase data for multiple times and retain saved data even when power is off, has become a memory device widely used in personal computers and electronic apparatuses.

FIGS. 1A-1D are cross-sectional views showing a process of a conventional method of fabricating a non-volatile memory.

Referring to FIG. 1A, a substrate 100 is provided. Isolation structures (not shown) are formed in the substrate 100 to define the active region. Then, a composite dielectric layer 101 is formed over the substrate 100. Wherein, the composite dielectric layer 101 is composed of a silicon oxide layer 102, a silicon nitride layer 104, and a barrier silicon oxide layer 106, for example. Then, a polysilicon layer 108 is formed over the barrier silicon oxide layer 106.

Referring to FIG. 1B, the polysilicon layer 108 and the composite dielectric layer 101 are patterned to form a plurality of stacked gate structures 110 over the substrate 100. Then, silicon oxide layers 112 are formed on the sidewalls of the stacked gate structures 110. A spacer material layer (not shown) is formed over the substrate 100. A portion of the spacer material layer is removed by an anisotropic etch process to form spacers 114 on the sidewalls of the stacked gate structures 110. Moreover, the spacers 114 cover the silicon oxide layers 112. Wherein, the stacked gate structure 110, the silicon oxide layer 112 and the spacers 114 constitute a memory cell 118.

Referring to FIG. 1C, another composite dielectric layer 101a is formed over the substrate 100, and the composite dielectric layer 101a covers the substrate 100, the stacked gate structures 110, the silicon oxide layers 112, and the spacers 114. Wherein, the composite dielectric layer 101a described above is composed of a silicon oxide layer 102a, a silicon nitride layer 104a, and a barrier silicon oxide layer 106a, for example. A polysilicon layer 116 is then formed over the composite dielectric layer 101a.

Referring to FIG. 1D, a planarization process is performed to remove a portion of the polysilicon layer 116 and a portion of the composite dielectric layer 101a until the surface of the stacked gate structures 110 is exposed. At this moment, another memory cell 120 is formed between two neighboring memory cells 118. The memory cell 120 is composed of the polysilicon layer 116a and the composite dielectric layer 101a.

Referring to FIG. 1D, in the process described above, the space between two neighboring memory cells 118 is adapted to accommodate another memory cell 120 so that the integration of the memory is increased. The non-volatile memory cell described above, however, has some disadvantages. During the process of fabricating the non-volatile memory cell shown in FIGS. 1A-1D, the composite dielectric layer 101 of the memory cell 118 and the composite dielectric layer 101a of the memory cell 120 are not formed in the same process, thus the fabricating process is more complicated.

In addition, since the composite dielectric layer 101 of the memory cell 118 and the composite dielectric layer 101a of the memory cell 120 are not formed in the same process, the composite dielectric layers 101 and 101a have reliability issues. In detail, since formed between two memory cells 118, the composite dielectric layer 101a of the memory cell 120 is formed on a non-uniform surface. As a result, the performance of the memory cells 118 and 120 may be different. The corners of the memory cell 120 and the substrate 100 would have uneven thickness, thus the composite dielectric layer 101 and 101a have different film qualities. As a result, the performance of the memory cells 118 and 120 is adversely affected, and the reliability of the memory is lowered.

### SUMMARY OF THE INVENTION

Accordingly, the present invention is directed to a method of fabricating a non-volatile memory, which has a simple process flow, and can enhance the reliability of the memory devices.

The present invention is also directed to a method of fabricating a non-volatile memory capable of improving the reliability of the film, and increasing the integration of the memory and the device performance.

The present invention is also directed to a method of fabricating a non-volatile memory capable of integrating the process of fabricating the memory cell region and the peripheral circuit region and increasing the reliability of the memory devices and the device performance.

The present invention provides a method of fabricating a non-volatile memory. In this method, a substrate is provided. A tunneling dielectric layer is formed over the substrate. A charge trapping layer is formed over the tunneling dielectric layer. A barrier dielectric layer then is formed over the charge trapping layer. A pad conductive layer is formed over the barrier dielectric layer. The pad conductive layer includes a plurality of openings therein. The openings expose a surface of the barrier dielectric layer. Then, portions of the barrier dielectric layer, the charge trapping layer, the tunneling dielectric layer, and the substrate, which are not covered by the pad conductive layer, are removed to form a plurality of trenches. A dielectric layer is filled in the trenches to form a plurality of trench isolation structures. A conductive layer is formed over the pad conductive layer. The conductive layer and the pad conductive layer are defined to form a plurality of stacked gate structures. Portions of the barrier dielectric layer, the charge trapping layer and the tunneling dielectric layer, which are not covered by the stacked gate structures, are removed. Then, a plurality of doped regions are formed within the substrate adjacent to two sides of each of the stacked gate structures.

According to an embodiment of the present invention, the method of forming the tunneling dielectric layer described above can be, for example, a thermal oxidation method. Wherein, the material of the tunneling dielectric layer can be, for example, silicon oxide.

According to an embodiment of the present invention, the method of forming the charge trapping layer described above can be, for example, a chemical vapor deposition (CVD) method. Wherein, the material of the charge trapping layer can be, for example, silicon nitride or doped polysilicon.

According to an embodiment of the present invention, the method of forming the barrier dielectric layer described above can be, for example, a CVD method. Wherein, the material of the barrier dielectric layer can be, for example, silicon oxide.

According to an embodiment of the present invention, the material of the pad conductive layer described above can be, for example, doped polysilicon.

According to an embodiment of the present invention, the method of forming the dielectric layer described above can be, for example, a high density plasma CVD (HDP CVD) method.

The present invention provides another method of fabricating a non-volatile memory. In this method, a tunneling dielectric layer, a charge trapping layer, and a barrier dielectric layer are sequentially formed over a substrate. A pad conductive layer is formed over the barrier dielectric layer. A plurality of trench isolation structures then are formed in the pad conductive layer, the barrier dielectric layer, the charge trapping layer, the tunneling dielectric layer, and a portion of the substrate. Then, a first conductive layer is formed over the pad conductive layer. The first conductive layer and the pad conductive layer are defined to form a plurality of first stacked gate structures, wherein every two first stacked structures are separated with a space. A plurality of dielectric layers are formed on sidewalls of the first stacked structures. A second dielectric layer is formed on an exposed surface of the barrier dielectric layer. A second conductive layer then is formed over the second dielectric layer to form a plurality of second stacked structures in the spaces. The barrier dielectric layer, the charge trapping layer, the tunneling dielectric layer, and the second dielectric layer, which are not covered by the first and second stacked gate structures, are removed. Two doped regions are formed within the substrate adjacent to a left side and a right side of the first stacked gate structures and the second stacked gate structures.

According to an embodiment of the present invention, the method of forming the tunneling dielectric layer described above can be, for example, a thermal oxidation method. Wherein, the material of the tunneling dielectric layer can be, for example, silicon oxide.

According to an embodiment of the present invention, the method of forming the charge trapping layer described above can be, for example, a chemical vapor deposition (CVD) method. Wherein, the material of the charge trapping layer can be, for example, silicon nitride or doped polysilicon.

According to an embodiment of the present invention, the method of forming the barrier dielectric layer described above can be, for example, a CVD method. Wherein, the material of the barrier dielectric layer can be, for example, silicon oxide.

According to an embodiment of the present invention, the method of forming the second dielectric layer described above can be, for example, a CVD method. Wherein, the material of the second dielectric layer can be, for example, silicon oxide.

The present invention provides a method of fabricating a non-volatile memory. In this method, a substrate is provided. The substrate includes a memory cell region and a peripheral circuit region. A tunneling dielectric layer is formed over the substrate. A charge trapping layer is formed over the tunneling dielectric layer. A barrier dielectric layer then is formed over the charge trapping layer. The barrier dielectric layer, the charge trapping layer, and the tunneling dielectric layer, which are in the peripheral circuit region, are removed. A gate oxide layer then is formed over the substrate in the peripheral circuit region. A pad conductive layer is formed over the barrier dielectric layer of the memory cell, and the gate oxide layer in the peripheral circuit region. Then, a plurality of first trench isolation structures are formed in the pad conductive layer, the barrier dielectric layer, the charge trapping layer, the tunneling dielectric layer, and a portion of the substrate, which are in the memory cell region. A plurality of second trench isolation structures are formed in the pad conductive layer, the gate oxide layer, and a portion of the substrate, which are in the peripheral circuit region. A conductive layer is formed over the pad conductive layer. The conductive layer and the pad conductive layer are defined to form a plurality of first stacked gate structures in the memory cell region, and a plurality of second stacked gate structures in the peripheral circuit region. The barrier dielectric layer, the charge trapping layer, and the tunneling dielectric layer, which are not covered by the first stacked gate structures, are removed. The gate oxide layer, which is not covered by the second stacked gate structures, is also removed. A plurality of first doped regions are formed in the substrate adjacent to two sides of each of the first stacked gate structures, and a plurality of second doped regions are formed in the substrate adjacent to two sides of each of the second stacked gate structures.

According to an embodiment of the present invention, the method of forming the tunneling dielectric layer described above can be, for example, a thermal oxidation method. Wherein, the material of the tunneling dielectric layer can be, for example, silicon oxide.

According to an embodiment of the present invention, the method of forming the charge trapping layer described above can be, for example, a chemical vapor deposition (CVD) method. Wherein, the material of the charge trapping layer can be, for example, silicon nitride or doped polysilicon.

According to an embodiment of the present invention, the method of forming the barrier dielectric layer described above can be, for example, a CVD method. Wherein, the material of the barrier dielectric layer can be, for example, silicon oxide.

In the method of fabricating the non-volatile memory, a gate structure is formed by using the space between two neighboring stacked gate structures without using a photolithographic and etching process. The method of the present invention is simple, and has low manufacturing costs. In addition, according to the method of the present invention, the film qualities and reliabilities of the tunneling dielectric layer, the charge trapping layer, and the barrier dielectric layer of the stacked gate structure, and the dielectric layer between the neighboring stacked gate structures are improved. Moreover, the stacked gate structures formed on the substrate and the gate structures formed between every two neighboring stacked gate structures share the same tunneling dielectric layer and the charge trapping layer. Compared with the conventional method, the method of the present invention has a simpler process, and can better improve the reliabilities of the memory devices.

The above and other features of the present invention will be better understood from the following detailed description of the preferred embodiments of the invention that is provided in communication with the accompanying drawings.

### BRIEF DESCRIPTION OF THE DRAWINGS

FIGS. 1A-1D are cross-sectional views showing a process of a conventional method of fabricating a non-volatile memory.

FIGS. 2A-2F are 3D configurations showing a process of a method of fabricating a non-volatile memory according to an embodiment of the present invention.

FIGS. 3A-3D are cross-sectional views of the non-volatile memory along line I-I′ of FIGS. 2A-2D.

FIGS. 3E and 3F are cross-sectional views of the non-volatile memory along line II-II′ of FIGS. 2E and 2F.

FIGS. 4A-4E are cross-sectional views showing a process of a method of fabricating a non-volatile memory according to another embodiment of the present invention.

FIGS. 5A-5F are cross-sectional views showing a process of a method of fabricating a non-volatile memory according to an embodiment of the present invention.

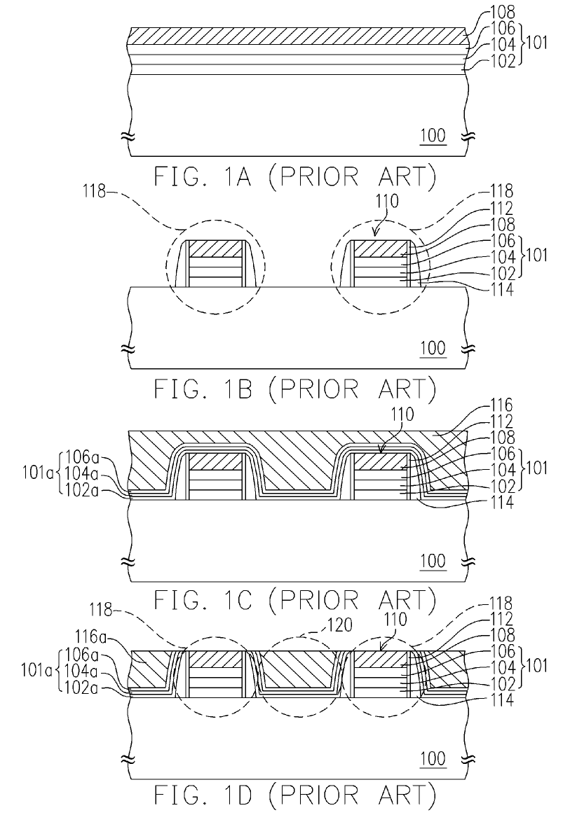

### DESCRIPTION OF SOME EMBODIMENTS

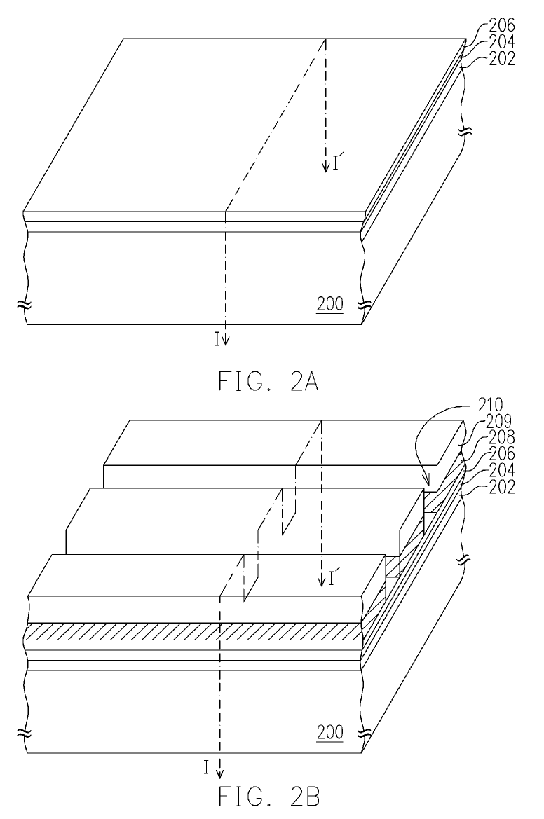

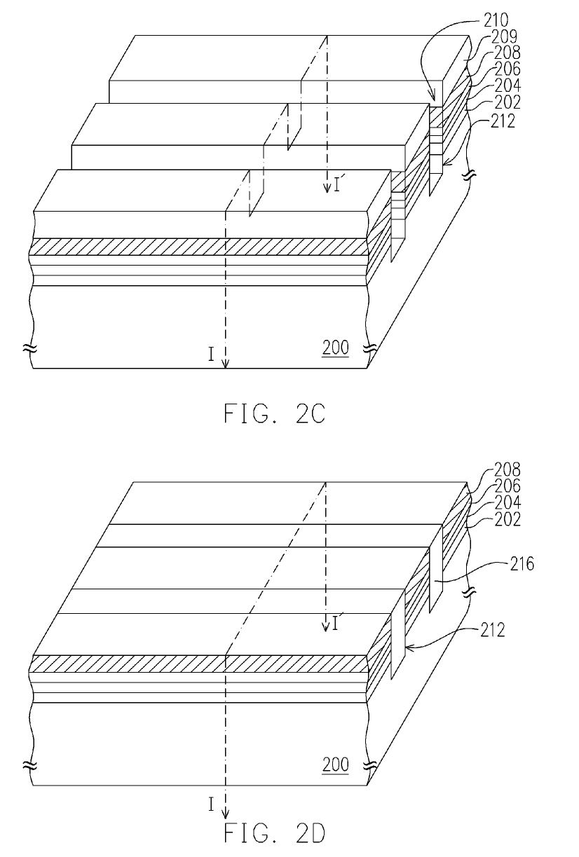

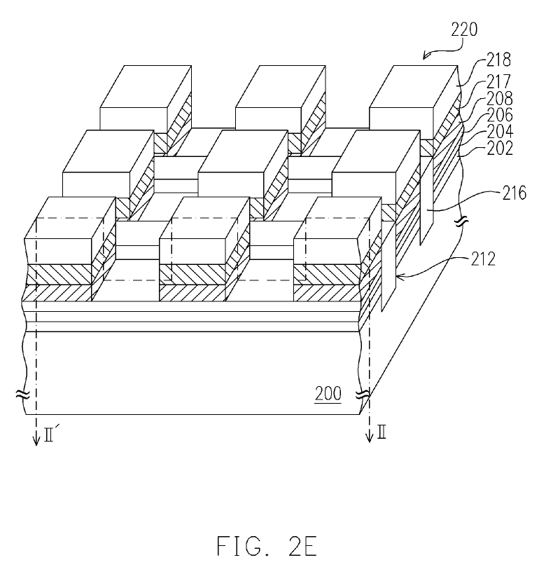

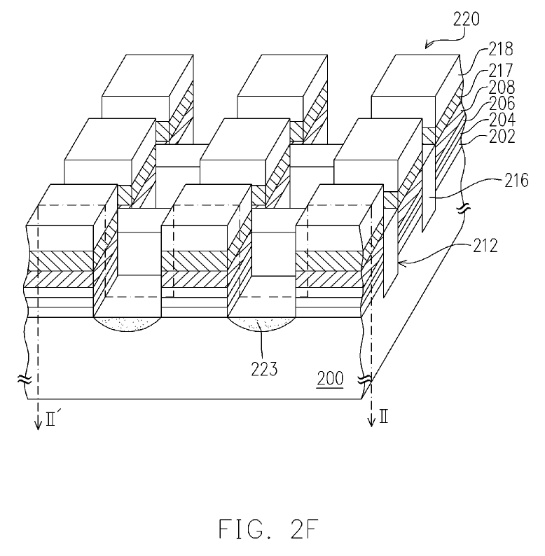

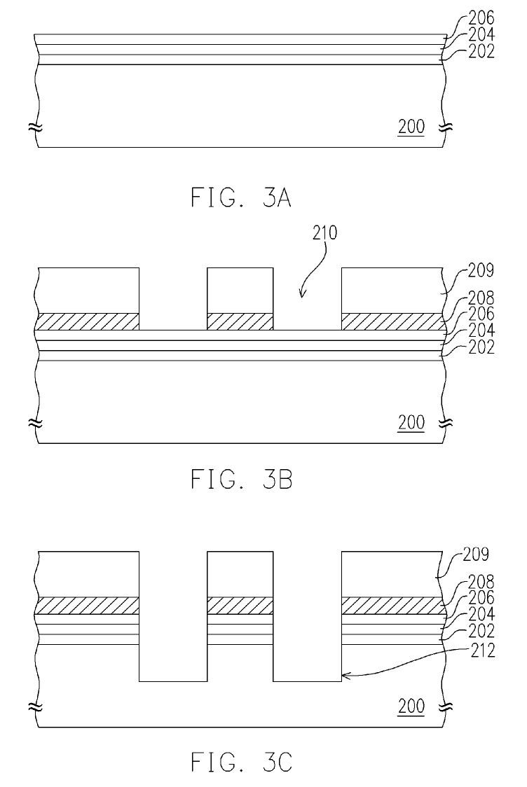

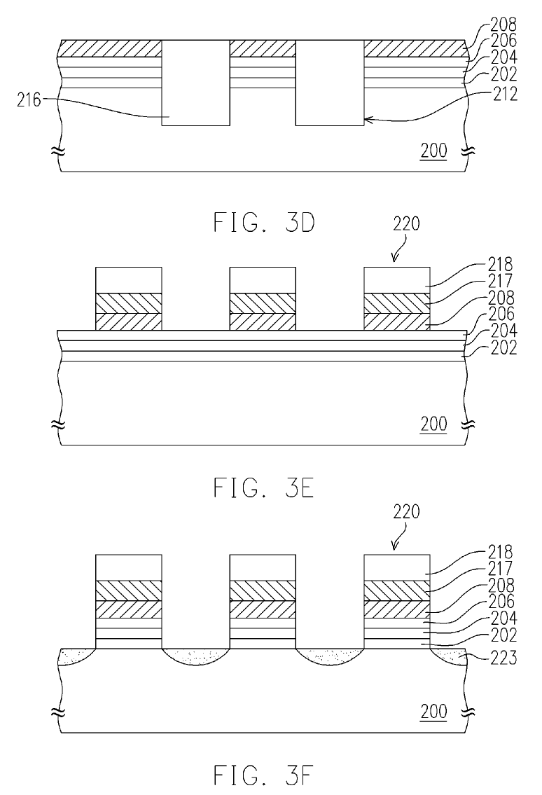

FIGS. 2A-2F are 3D configurations showing a process of a method of fabricating a non-volatile memory according to an embodiment of the present invention. FIGS. 3A-3D are cross-sectional views of the non-volatile memory along line I-I′ of FIGS. 2A-2D. FIGS. 3E and 3F are cross-sectional views of the non-volatile memory along line II-II′ of FIGS. 2E and 2F.

Referring to FIGS. 2A and 3A, a substrate 200 is provided. The substrate 200 can be, for example, a silicon substrate. Then, a tunneling dielectric layer 202, a charge trapping layer 204, and a barrier dielectric layer 206 are sequentially formed over the substrate 200. Wherein, the material of the tunneling dielectric layer 202 can be, for example, silicon oxide. The method of forming the tunneling dielectric layer 202 can be, for example, a thermal oxidation method. The material of the charge trapping layer 204 can be, for example, silicon nitride or doped polysilicon. The method of forming the charge trapping layer 204 can be, for example, a chemical vapor deposition (CVD) method. The material of the barrier dielectric layer 206 can be, for example, silicon oxide. The method of forming the barrier dielectric layer 206 can be, for example, a CVD method. In some embodiments, the materials of the tunneling dielectric layer 202 and the barrier dielectric layer 206 can be other materials. The material of the charge trapping layer 204 is not limited to silicon nitride, but can be other materials, such as a tantalum oxide layer, a strontium titanate layer, or a hafnium oxide layer that can trap charges therein.

Referring to FIGS. 2B and 3B, a pad conductive layer 208 is formed over the barrier dielectric layer 206. The pad conductive layer 208 includes a plurality of openings 210 therein. The openings 210 expose the surface of the barrier dielectric layer 206. Wherein, the material of the pad conductive layer 208 can be, for example, doped polysilicon. Additionally, the method of forming the openings 210 includes: forming a patterned mask layer 209 over the pad conductive layer 208, and performing an etch process to the pad conductive layer 208 using the patterned mask layer 209 as a mask, for example. Wherein, the material of the patterned mask layer 209 can be, for example, silicon nitride or other materials that have an etching selectivity different from that of the pad conductive layer 208. The patterned mask layer 209 covers and protects the pad conductive layer 208 from damages during a photolithographic process and an etching process.

Referring to FIGS. 2C and 3C, the barrier dielectric layer 206, the charge trapping layer 204, the tunneling dielectric layer 202 and a portion of the substrate 200, which are not covered by the patterned mask layer 209 and by the pad conductive layer 208, are removed to form a plurality of trenches 212. Wherein, the method of forming the trenches 212 includes removing the barrier dielectric layer 206, the charge trapping layer 204, the tunneling dielectric layer 202, and a portion of the substrate 200 by using the patterned mask layer 209 and the pad conductive layer 208 as an etching mask, for example.

Referring to FIGS. 2D and 3D, a dielectric layer is filled in the trenches 212 to form a plurality of trench isolation structures 216. Wherein, the material of the dielectric layer can be, for example, silicon oxide. The method of forming the dielectric layer can be, for example, a high density plasma CVD method (HDP CVD). Additionally, in the method of forming the trench isolation structures 216, a dielectric material layer (not shown) is formed over the substrate 200, for example. The dielectric material layer covers the patterned mask layer 209 and fills the trenches 212. By a chemical-mechanical polishing (CMP) method or an etching-back process, a portion of the dielectric material layer and the patterned mask layer 209 are removed until the surface of the pad conductive layer 208 is exposed. Note that the remaining pad conductive layer 208 protects the barrier dielectric layer 206, the charge trapping layer 204, and the tunneling dielectric layer 202. Accordingly, the film qualities of the barrier dielectric layer 206, the charge trapping layer 204, and the tunneling dielectric layer 202 are maintained.

Referring to FIGS. 2E and 3E, a conductive layer 217 is formed over the pad conductive layer 208. Wherein, the material of the conductive layer 217 can be, for example, doped polysilicon. The method of forming the conductive layer 217 includes: forming an undoped polysilicon layer by a CVD method, and performing an ion implantation process to the undoped polysilicon layer, for example. In an embodiment, in the method of forming the conductive layer 217, stripe conductive material layers (not shown) are formed over the pad conductive layer 208, for example. A patterned cap layer 218 then is formed over the conductive layer 216. Wherein, the material of the patterned cap layer 218 can be, for example, silicon nitride. Then, the conductive material layers and the pad conductive layer 208 are defined by the patterned cap layer 218 to form a plurality of stacked gate structures 220.

Referring to FIGS. 2F and 3F, the barrier dielectric layer 206, the charge trapping layer 204, and the tunneling dielectric layer 202, which are not covered by the stacked gate structures 220, are removed. In this step, by using the stacked gate structures 220 as a mask, for example, portions of the barrier dielectric layer 206, the charge trapping layer 204, and the tunneling dielectric layer 202 are etched and removed. Then, a plurality of doped regions 223 are formed within the substrate 200 adjacent to two sides of each stacked gate structure 220. Wherein, the method of forming the doped regions 223 can be, for example, a doping process.

Accordingly, the tunneling dielectric layer 202, the charge trapping layer 204, and the barrier dielectric layer 206 are formed before the trench isolation structures 216 are formed. The remaining pad conductive layer 208 protects the tunneling dielectric layer 202, the charge trapping layer 204, and barrier dielectric layer 206. Accordingly, the thinning film layer at the corners of the trench isolation structures 216 can be avoided, while the trench isolation structures 216 are formed. In other words, the tunneling dielectric layer 202, the charge trapping layer 204, and the barrier dielectric layer 206 formed according to the present invention have uniform thicknesses, better film qualities, and better reliabilities.

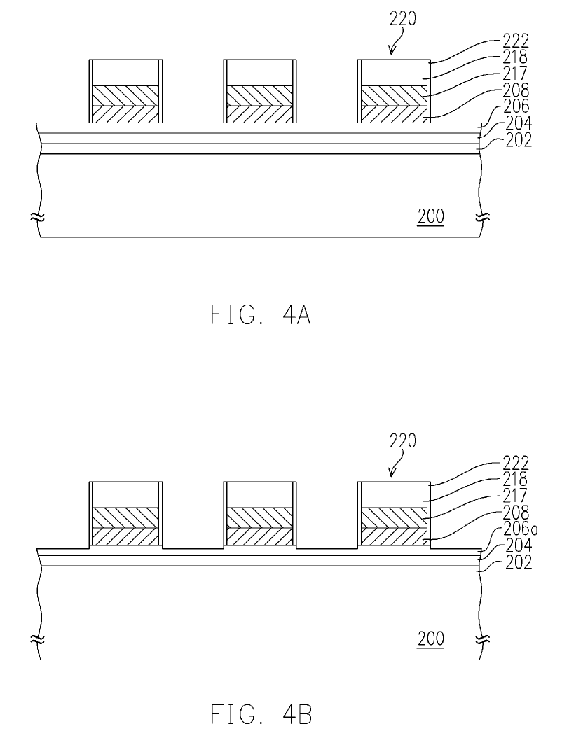

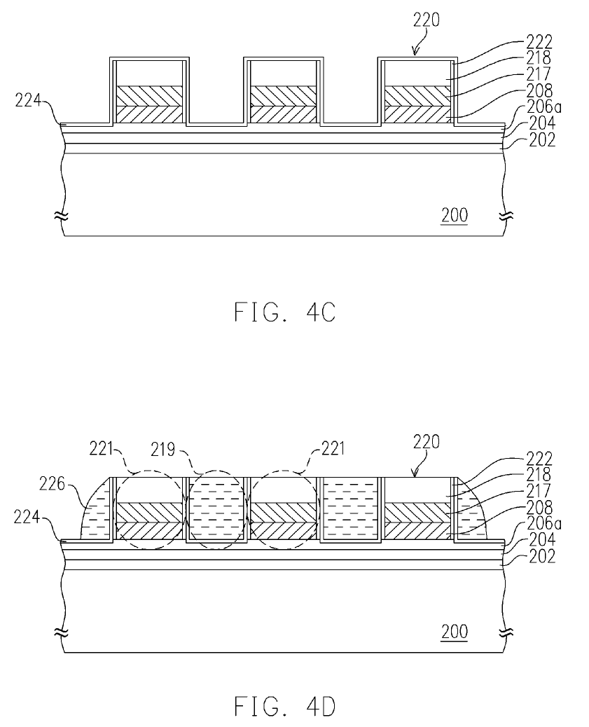

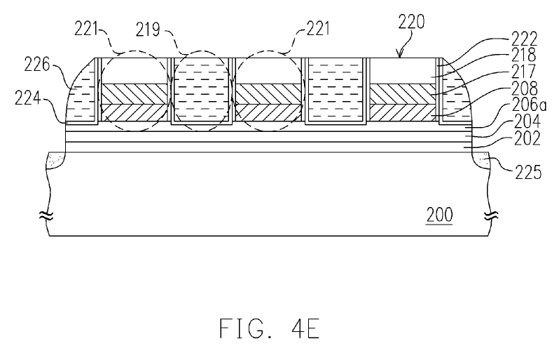

In addition to the embodiment described above, the present invention also provides other embodiments. FIGS. 4A-4E are cross-sectional views showing a process of a method of fabricating a non-volatile memory according to another embodiment of the present invention. Wherein, the FIG. 4A follows the step in FIG. 3E. In FIGS. 4A-4D, similar elements as those of FIGS. 3A-3E are marked with the same numerals. Detailed descriptions are not repeated.

Referring to FIG. 4A, after the stacked gate structures 220 is formed, a dielectric layer 222 is formed on the sidewalls of the stacked gate structures 220. The material of the dielectric layer 222 can be, for example, silicon oxide. The method of forming the dielectric layer 222 can be, for example, a thermal oxidation method. Wherein, the dielectric layer 222 is adapted to electrically isolate two conductive layers.

Referring to FIG. 4B, a portion of the barrier dielectric layer 206, which is not covered by the stacked gate structures 220 and the dielectric layer 222, is removed. Wherein, the method of removing the portion of the barrier dielectric layer 206 can be, for example, an etching process.

Referring to FIG. 4C, a dielectric layer 224 is formed over the substrate 200. The dielectric layer 224 covers the stacked gate structures 220, the dielectric layer 222 and the exposed barrier dielectric layer 206a. Wherein, the material of the dielectric layer 224 can be, for example, silicon oxide. The method of forming the dielectric layer 224 can be, for example, a CVD method. Note that the dielectric layer 224 in the space and on the sidewalls of two neighboring stacked gate structures 220 serves for electrical isolation. The dielectric layer 224 on the barrier dielectric layer 206a serves as a barrier dielectric layer.

Referring to FIG. 4D, a conductive layer 226 is formed over the dielectric layer 224. Wherein, the material of the conductive layer 226 can be, for example, doped polysilicon. The method of forming the conductive layer 226 includes: forming an undoped polysilicon layer by a CVD method, and performing an ion implantation process to the undoped polysilicon layer, for example. Then, a portion of the conductive layer 226 and a portion of the dielectric layer 224 are removed to expose the surface of the stacked gate structures 220 so as to form another stacked gate structures in the space between every two neighboring stacked gate structures 220.

Referring to FIG. 4E, the barrier dielectric layer 206a, the charge trapping layer 204, the tunneling dielectric layer 202, and the dielectric layer 224, which are not covered by the stacked gate structures 220 and the conductive layer 226, are removed. Then, the doped regions 225 and 226 are formed within the substrate 200 adjacent to the left side and the right side of the stacked gate structures 220 and the conductive layer 226. Wherein, the doped regions 225 and 226 serve as the source and drain of the non-volatile memory. Then, subsequent processes of forming the non-volatile memory in the conventional technology are performed. One of ordinary skill in the art would know these subsequent processes so details are not mentioned.

In the embodiment described above, the tunneling dielectric layer 202, the charge trapping layer 204, the barrier dielectric layer 206, the dielectric layer 222, and the stacked gate structure 220 constitute a memory cell 221. The tunneling dielectric layer 202, the charge trapping layer 204, the barrier dielectric layer 206a, the dielectric layer 224, and the conductive layer 226 constitute another memory cell 219. Wherein, the memory cell 219 is formed in the space between two neighboring memory cells 221. The integration of the memory thus is increased. Moreover, the tunneling dielectric layer 202 and the charge trapping layer 204 of the memory cells 219 and 221 are formed in the same process, and on a uniform surface. Therefore, they have better film qualities and better reliabilities of the memory cells. In another aspect, the memory cells 219 and 221 share the tunneling dielectric layer 202 and the charge trapping layer 204. Therefore, the steps of manufacturing the memory are reduced, and the manufacturing costs are also down.

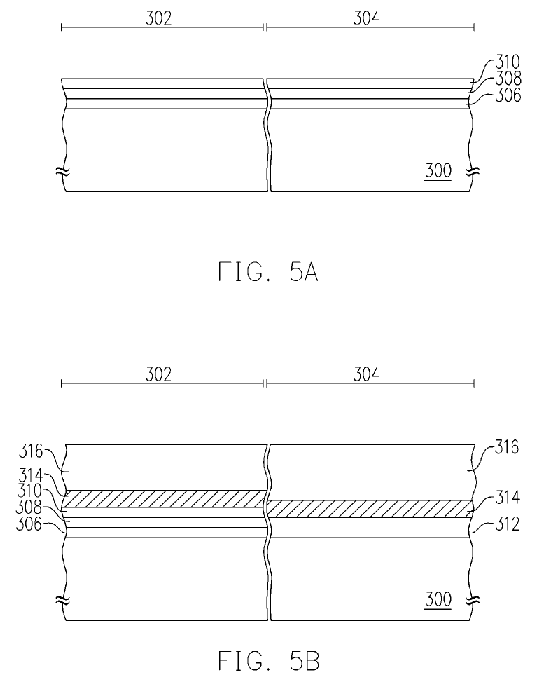

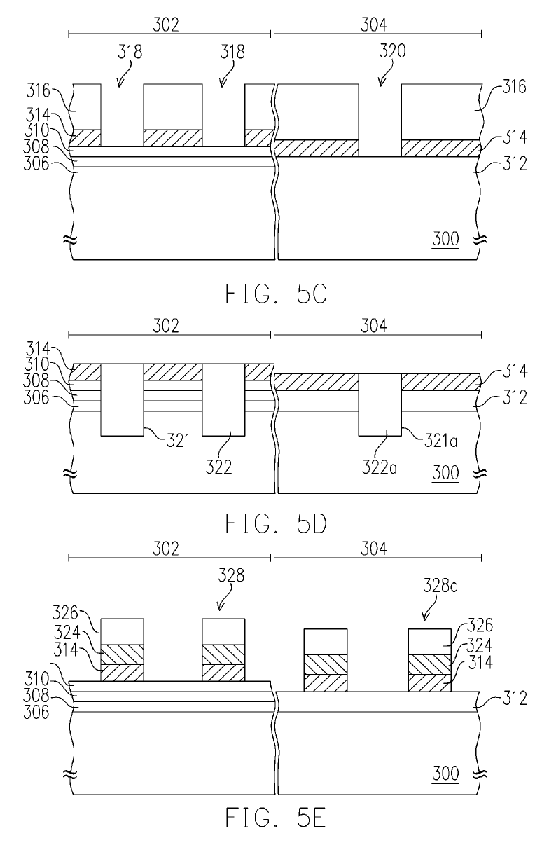

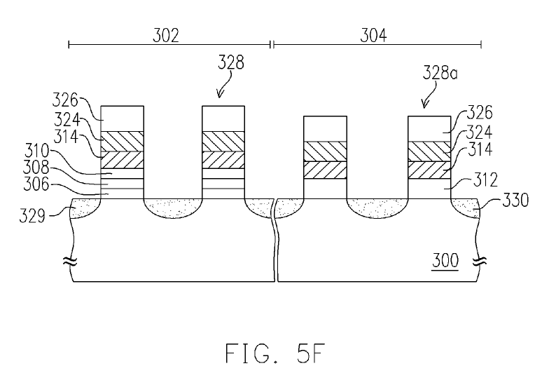

In addition, the method of fabricating the non-volatile memory according to the present invention can be integrated with the process of forming peripheral circuit region to fabricate the non-volatile memory with memory cell region and the peripheral circuit region on the same wafer. FIGS. 5A-5F are cross-sectional views showing a process of a method of fabricating a non-volatile memory according to an embodiment of the present invention.

Referring to FIG. 5A, a substrate 300 is provided. Wherein, the substrate 300 includes a memory cell region 302 and a peripheral circuit region 304. Then, the tunneling dielectric layer 306, the charge trapping layer 308, and the barrier dielectric layer 310 are sequentially formed over the substrate 300.

Referring to FIG. 5B, the tunneling dielectric layer 306, the charge trapping layer 308, and the barrier dielectric layer 310, which are in the peripheral circuit region 304, are removed. Then, the gate oxide layer 312 is formed over the surface of the substrate 300 in the peripheral circuit region 304. Wherein, the material of the gate oxide layer 312 can be, for example, silicon oxide. The method of forming the gate oxide layer 312 can be, for example, a wet oxidation method. Then, the pad conductive layer 314 and the mask layer 316 are formed over the barrier dielectric layer 310 in the memory cell region 302, and over the gate oxide layer 312 in the peripheral circuit region 304.

Referring to FIG. 5C, a photolithographic process and an etching process are performed to remove a portion of the mask layer 316 and the pad conductive layer 314 so as to form the opening 318 exposing the barrier dielectric layer 310 in the memory cell region 302, and the opening 320 exposing the gate oxide layer 312 in the peripheral circuit region 304.

Referring to FIG. 5D, the trench isolation structures 322 are formed in the pad conductive layer 314, the barrier dielectric layer 310, the charge trapping layer 308, the tunneling dielectric layer 306, and a portion of the substrate 300, which are in the memory cell region 302. In addition, the trench isolation structures 322a are formed in the pad conductive layer 314, the gate oxide layer 312, and a portion of the substrate 300, which are in the peripheral circuit region 304. In the step of forming the trench isolation structures 322 and 322a, the barrier dielectric layer 310, the charge trapping layer 308, the tunneling dielectric layer 306, and a portion of the substrate 300, which are in the memory cell region 302, are removed; and the gate oxide layer 312 and a portion of the substrate 300, which are in the peripheral circuit region 304, are removed by using the mask layer 316 as an etch mask, for example. Accordingly, the trenches 321 and 321a are formed. A dielectric layer then is formed on the substrate 300 to fill the trenches 321 and 321a in the memory cell region 302 and the peripheral circuit region 304, respectively. The dielectric layer covers the mask layer 316. Then, a portion of the dielectric layer and the mask layer 316 are removed until the surface of the pad conductive layer 314 is exposed.

Referring to FIG. 5E, a conductive layer 324 is formed over the pad conductive layer 314. In an embodiment of forming the conductive layer 324, strip conductive material layers (not shown) are formed over the pad conductive layer 314. A patterned cap layer 326 is then formed over the conductive material layers. The conductive material layers and the pad conductive layer 314 are defined by using the patterned cap layer 326 to form a plurality of stacked gate structures 328 in the memory cell region 302, and a plurality of stacked gate structures 328a in the peripheral circuit region 304.

Referring to FIG. 5F, the barrier dielectric layer 310, the charge trapping layer 308, and the tunneling dielectric layer 306, which are not covered by the stacked gate structures 328, and the gate oxide layer 312, which is not covered by the gate stacked structures 328a, are removed. In this embodiment, for example, portions of the barrier dielectric layer 310, the charge trapping layer 308, and the tunneling dielectric layer 306 are etched by using the stacked structures 328 as an etching mask; and a portion of the gate oxide layer 312 is etched using the gate stacked structures 328a as an etching mask. Then, a plurality of doped regions 329 are formed in the substrate 300 adjacent to two sides of each stacked gate structure 328. In addition, a plurality of doped regions 330 are formed in the substrate 300 adjacent to two sides of each stacked gate structure 328a. Wherein, the method of forming the doped regions 329 and 330 can be, for example, a doping process.

Under the similar situation, subsequent processes of forming the non-volatile memory in the conventional technology are performed. One of ordinary skill in the art would know these subsequent processes so details are not mentioned.

Accordingly, the present invention includes at least the following advantages:

According to the method of the present invention, another memory cell is formed between two neighboring memory cells without a photolithographic process and an etching process. Not only is the manufacturing process simplified, the integration of the memory is also improved, and the manufacturing costs are reduced.

According to the method of the present invention, the tunneling dielectric layer 202 and the charge trapping layer 204 of the memory cells 219 and 221 are formed in the same process, and on a uniform surface. Therefore, the memory devices have better film qualities, and improved reliabilities.

According to the method of the present invention, the memory cells 219 and 221 share the same tunneling dielectric layer and the charge trapping layer. The process flow of manufacturing the memory is reduced, and the manufacturing costs are reduced as well.

According to the method of the present invention, the processes of fabricating the memory cell region and the peripheral circuit region of the non-volatile memory are integrated. Thus, the fabricating process is simplified, and the reliabilities of the memory and the device performance are improved.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A method of fabricating a non-volatile memory, comprising:
providing a substrate;
forming a tunneling dielectric layer over the substrate;
forming a charge trapping layer over the tunneling dielectric layer;
forming a barrier dielectric layer over the charge trapping layer;
forming a pad conductive layer over the barrier dielectric layer, the pad conductive layer comprising a plurality of openings therein, the openings exposing a surface of the barrier dielectric layer;
removing portions of the barrier dielectric layer, the charge trapping layer, the tunneling dielectric layer, and the substrate, which are not covered by the pad conductive layer, to form a plurality of trenches;
filling a dielectric layer in the trenches to form a plurality of trench isolation structures;
forming a conductive layer over the pad conductive layer;
defining the conductive layer and the pad conductive layer to form a plurality of stacked gate structures;
removing portions of the barrier dielectric layer, the charge trapping layer and the tunneling dielectric layer, which are not covered by the stacked gate structures; and
forming a plurality of doped regions within the substrate adjacent to two sides of each of the stacked gate structures.

2. The method of fabricating a non-volatile memory of claim 1, wherein a method of forming the tunnel dielectric layer comprises a thermal oxidation method.

3. The method of fabricating a non-volatile memory of claim 1, wherein a material of the tunneling dielectric layer comprises silicon oxide.

4. The method of fabricating a non-volatile memory of claim 1, wherein a method of forming the charge trapping layer comprises a chemical vapor deposition (CVD) method.

5. The method of fabricating a non-volatile memory of claim 1, wherein a material of the charge trapping layer comprises silicon nitride or doped polysilicon.

6. The method of fabricating a non-volatile memory of claim 1, wherein a method of forming the barrier dielectric layer comprises a chemical vapor deposition (CVD) method.

7. The method of fabricating a non-volatile memory of claim 1, wherein a material of the barrier dielectric layer comprises silicon oxide.

8. The method of fabricating a non-volatile memory of claim 1, wherein a material of the pad conductive layer comprises doped polysilicon.

9. The method of fabricating a non-volatile memory of claim 1, wherein a method of forming the dielectric layer comprises a high density plasma chemical vapor deposition (HDP CVD) method.

10. A method of fabricating a non-volatile memory, comprising:
sequentially forming a tunneling dielectric layer, a charge trapping layer, and a barrier dielectric layer over a substrate;
forming a pad conductive layer over the barrier dielectric layer;
forming a plurality of trench isolation structures in the pad conductive layer, the barrier dielectric layer, the charge trapping layer, the tunneling dielectric layer, and a portion of the substrate;
forming a first conductive layer over the pad conductive layer;
defining the first conductive layer and the pad conductive layer to form a plurality of first stacked gate structures, wherein every two first stacked structures are separated from each other by a gap;
forming a plurality of dielectric layers on sidewalls of the first stacked gate structures;
forming a second dielectric layer on an exposed surface of the barrier dielectric layer;
forming a second conductive layer over the second dielectric layer to form a plurality of second stacked gate structures in the spaces, wherein the first stacked gate structures and the second stacked gate structures form a memory cell column;
removing the barrier dielectric layer, the charge trapping layer, the tunneling dielectric layer, and the second dielectric layer, which are not covered by the first stacked gate structures and the second stacked gate structures; and
forming two doped regions within the substrate on a left side and a right side of the memory cell column.

11. The method of fabricating a non-volatile memory of claim 10, wherein a method of forming the tunneling dielectric layer comprises a thermal oxidation method.

12. The method of fabricating a non-volatile memory of claim 10, wherein a material of the tunneling dielectric layer comprises silicon oxide.

13. The method of fabricating a non-volatile memory of claim 10, wherein a method of forming the charge trapping layer comprises a chemical vapor deposition (CVD) method.

14. The method of fabricating a non-volatile memory of claim 10, wherein a material of the charge trapping layer comprises silicon nitride or doped polysilicon.

15. The method of fabricating a non-volatile memory of claim 10, wherein a method of forming the barrier dielectric layer comprises a chemical vapor deposition (CVD) method.

16. The method of fabricating a non-volatile memory of claim 10, wherein a material of the barrier dielectric layer comprises silicon oxide.

17. The method of fabricating a non-volatile memory of claim 10, wherein a method of forming the second dielectric layer comprises a chemical vapor deposition (CVD) method.

18. The method of fabricating a non-volatile memory of claim 10, wherein a material of the second dielectric layer comprises silicon oxide.

19. A method of fabricating a non-volatile memory, comprising:
providing a substrate, the substrate comprising a memory cell region and peripheral circuit region;
forming a tunneling dielectric layer over the substrate;
forming a charge trapping layer over the tunneling dielectric layer;
forming a barrier dielectric layer over the charge trapping layer;
removing portions of the barrier dielectric layer, the charge trapping layer, and the tunneling dielectric layer, which are in the peripheral circuit region;
forming a gate oxide layer over the substrate in the peripheral circuit region;
forming a pad conductive layer over the barrier dielectric layer in the memory cell region, and over the gate oxide layer in the peripheral circuit region;
forming a plurality of first trench isolation structures in the pad conductive layer, the barrier dielectric layer, the charge trapping layer, the tunneling dielectric layer, and a portion of the substrate, which are in the memory cell region, and forming a plurality of second trench isolation structures in the pad conductive layer, the gate oxide layer, and a portion of the substrate, which are in the peripheral circuit region;
forming a conductive layer over the pad conductive layer;
defining the conductive layer and the pad conductive layer to form a plurality of first stacked gate structures in the memory cell region, and a plurality of second stacked gate structures in the peripheral circuit region;
removing the barrier dielectric layer, the charge trapping layer, and the tunneling dielectric layer, which are not covered by the first stacked gate structures, and the gate oxide layer, which is not covered by the second stacked gate structures; and
forming a plurality of first doped regions in the substrate adjacent to two sides of each first stacked gate structure, and a plurality of second doped regions in the substrate adjacent to two sides of each second stacked gate structure.

20. The method of fabricating a non-volatile memory of claim 19, wherein a method of forming the tunneling dielectric layer comprises a thermal oxidation method.

21. The method of fabricating a non-volatile memory of claim 19, wherein a material of the tunneling dielectric layer comprises silicon oxide.

22. The method of fabricating a non-volatile memory of claim 19, wherein a method of forming the charge trapping layer comprises a chemical vapor deposition (CVD) method.

23. The method of fabricating a non-volatile memory of claim 19, wherein a material of the charge trapping layer comprises silicon nitride or doped polysilicon.

24. The method of fabricating a non-volatile memory of claim 19, wherein a method of forming the barrier dielectric layer comprises a chemical vapor deposition (CVD) method.

25. The method of fabricating a non-volatile memory of claim 19, wherein a material of the barrier dielectric layer comprises silicon oxide.
